(19) United States
(12) Patent Application Publication
(10) Pub. No.: US 2019/0243498 A1
(43) Pub. Date: Aug. 8, 2019

(54) TOUCH DISPLAY SUBSTRATE, TOUCH DISPLAY DEVICE AND CONTROL METHOD OF THE SAME

(71) Applicant: BOE TECHNOLOGY GROUP CO., LTD., Beijing (CN)

(72) Inventors: Haisheng WANG, Beijing (CN); Xue DONG, Beijing (CN); Yingming LIU, Beijing (CN); Xiaoliang DING, Beijing (CN)

(73) Assignee: BOE TECHNOLOGY GROUP CO., LTD., Beijing (CN)

(21) Appl. No.: 16/341,346

(22) PCT Filed: Jul. 26, 2018
(86) PCT No.: PCT/CN2018/097157

§ 371 Date: Apr. 11, 2019

(30) Foreign Application Priority Data
Aug. 31, 2017 (CN) 201710771467.X

(51) Int. Cl. G06F 3/041; G06F 3/047; H01L 27/12

(52) U.S. Cl. CPC G06F 3/0412; H01L 27/1218; G06F 3/047; G06F 3/0414

(57) ABSTRACT

A touch display substrate, a touch display device, and a control method thereof are provided. The touch display substrate includes first electrodes on a base substrate and independent from each other, wherein each of the first electrodes is used as an electrode used for display in a display stage, is used as a touch electrode in a touch time stage and is used as a first pressure sensitive electrode in a pressure detection stage; pressure sensitive electrodes corresponding to the first electrodes on the base substrate; and a piezoelectric layer between the first electrodes and the second pressure sensitive electrodes.

### CROSS-REFERENCE TO RELATED APPLICATION

The present application claims a priority of a Chinese patent application No. 201710771467.X filed in China on Aug. 31, 2017, a disclosure of which is incorporated herein in its entirety by reference.

### TECHNICAL FIELD

The present disclosure relates to a field of display technology, and specifically relates to a touch display substrate, a touch display device, and a control method of the touch display device.

### BACKGROUND

A pressure sensitive function is an important function in a field of display sensors. Integrating pressure sensors in a display device is an important trend in display integration with sensors.

### SUMMARY

A touch display substrate, a touch display device, and a control method of the touch display device are provided in the present disclosure.

In a first aspect, a touch display substrate is provided and includes: a plurality of first electrodes on a base substrate and independent from each other, wherein each of the plurality of first electrodes is configured to be used as an electrode used for display in a display time stage, be used as a touch electrode in a touch time stage and be used as a first pressure sensitive electrode in a pressure detection time stage; a plurality of second pressure sensitive electrodes corresponding to the plurality of first electrodes on the base substrate; and a piezoelectric layer between the plurality of first electrodes and the plurality of second pressure sensitive electrodes.

Optionally, the touch display substrate further includes: a plurality of first pressure sensitive lines, wherein each of the first pressure sensitive lines is connected to one of the plurality of first electrodes corresponding to the each of the first pressure sensitive lines; and a second pressure sensitive line, connected to the plurality of second pressure sensitive electrodes.

Optionally, the plurality of first pressure sensitive lines and data lines on the touch display substrate are in a same layer and are formed of a same material, or the plurality of first pressure sensitive lines and gate lines on the touch display substrate are in a same layer and are formed of a same material, or the plurality of first pressure sensitive lines and pixel electrodes on the touch display substrate are in a same layer and are formed of a same material.

Optionally, the plurality of second pressure sensitive electrodes is formed of a metal, and each of the plurality of second pressure sensitive electrodes is in a non-aperture region of the touch display substrate.

Optionally, the touch display substrate further includes a thin film transistor (TFT) array layer on the base substrate; the data lines on the TFT array layer; and an insulation layer on the TFT array layer and covering the data lines; wherein the plurality of second pressure sensitive electrodes is on the insulation layer, the piezoelectric layer is on the plurality of second pressure sensitive electrodes and covers the insulation layer, and the plurality of first electrodes is on the piezoelectric layer.

Optionally, the piezoelectric layer is formed of Polyvinylidene fluoride.

Optionally, under a condition that the plurality of first pressure sensitive lines and data lines on the touch display substrate are in a same layer and are formed of a same material, each of the plurality of first pressure sensitive lines is connected to one of the first electrodes through a corresponding via-hole penetrating through the insulation layer and the piezoelectric layer. Under a condition that the plurality of first pressure sensitive lines and gate lines on the touch display substrate are in a same layer and are formed of the same material, if thin film transistors (TFTs) included in the TFT array layer are bottom-gate type TFTs, the each of the plurality of first pressure sensitive lines is connected to one of the first electrodes through a corresponding via-hole, wherein the corresponding via-hole penetrates through a gate-insulation layer above the gate lines and below the insulation layer, through the insulation layer and through the piezoelectric layer; if the TFTs included in the TFT array layer are top-gate type TFTs, then each of the plurality of first pressure sensitive lines is connected to one of the first electrodes through a corresponding via-hole penetrating through the insulation layer and the piezoelectric layer. Under a condition that the plurality of first pressure sensitive lines and pixel electrodes on the touch display substrate are in a same layer and are formed of a same material, each of the plurality of first pressure sensitive lines is connected to one of the first electrodes through a corresponding via-hole penetrating through a passivation layer on the first electrodes.

Optionally, the piezoelectric layer directly contacts with both the plurality of first electrodes and the plurality of second piezoelectric sensitive electrodes.

Optionally, the plurality of first pressure sensitive lines is used as the touch signal lines in the touch time stage.

Optionally, the plurality of first electrodes is a plurality of common electrodes arranged in a matrix form, each of the plurality of common electrodes corresponds to at least one second pressure sensitive electrode extending in a horizontal direction and at least two second pressure sensitive electrodes extending in a vertical direction; the at least one second pressure sensitive electrode extending in a horizontal direction corresponds to a same row of common electrodes of the plurality of common electrodes arranged in the matrix form, and the at least two second pressure sensitive electrodes extending in the vertical direction correspond to a same column of common electrodes of the plurality of common electrodes arranged in the matrix form.

Optionally, the at least one second pressure sensitive electrode extending in the horizontal direction intersects with, overlaps with, and is electrically connected with the at least two second pressure sensitive electrodes extending in the vertical direction, and a position at which each second pressure sensitive electrode extending in the horizontal direction overlaps with each second pressure sensitive electrode extending in the vertical direction is within a region of one of the common electrodes.

In a second aspect, a touch display device is provided in the present disclosure and includes the touch display substrate according to the first aspect.

In a third aspect, a method for controlling a touch display device, the touch display device being the touch display device according to the second aspect, the method includes: providing the plurality of first electrodes of the touch display substrate with common voltage signals, in the display time stage of the display period of one image frame; providing the plurality of first electrodes of the touch display substrate with a touch signal, in the touch time stage of the display period of the one image frame; and providing the plurality of first electrodes of the touch display substrate with a first reference electrical signal, in the pressure detection time stage of the display period of the one image frame, and providing the plurality of second pressure sensitive electrodes with a second reference electrical signal, wherein a predetermined voltage difference exists between the first reference electrical signal and the second reference electrical signal.

Optionally, the method further includes at least one of following (i) or (ii): (i) detecting, in the pressure detection time stage of the display period of the one image frame, a pressure sensitive signal in a corresponding first line connected to the each of the plurality of first electrodes; (ii) detecting, in the pressure detection time stage of the display period of the one image frame, a pressure sensitive signal in the second pressure sensitive line connected to the plurality of pressure sensitive electrodes.

Optionally, the plurality of first electrodes is a plurality of common electrodes, and the method further includes: providing the plurality of common electrodes of the touch display substrate with common voltage signals, in the display time stage of the display period of one image frame; providing the plurality of common electrodes of the touch display substrate with touch signals, in the touch time stage of the display period of the one image frame; and in the pressure detection time stage of the display period of the one image frame, at least one of (i) providing the plurality of common electrodes of the touch display substrate with the first reference electrical signal, or (ii) providing the plurality of second pressure sensitive electrodes with the second reference electrical signal.

### BRIEF DESCRIPTION OF THE DRAWINGS

FIG. 1 is a structural schematic diagram of a pressure sensitive unit in some embodiments of the present disclosure.

FIG. 2 is a structural schematic diagram of a touch display panel including a touch display substrate in some embodiments of the present disclosure.

FIG. 3 is a planar schematic diagram of a touch display substrate in some embodiments of the present disclosure.

FIG. 4 is another structural schematic diagram of a touch display panel including a touch display substrate in some embodiments of the present disclosure.

FIG. 5 is yet another structural schematic diagram of a touch display panel including a touch display substrate in some embodiments of the present disclosure.

FIG. 6 is a flowchart of a control method of a touch display device in some embodiments of the present disclosure.

### DETAILED DESCRIPTION

To make technical problems to be solved, technical solutions, and advantages of the present disclosure clearer, specific embodiments will be described hereinafter in detail in combination with drawings.

In a relevant art, pressure sensors and a display device are generally manufactured separately and then combined together, wherein the pressure sensors are arranged at a backplate of the display device, the display device integrated with the pressure sensors is thus thick and has a complex structure. The touch display substrate, the touch display device and the control method of the touch display device provided in the present disclosure enable the touch display substrate to be integrated with a pressure sensitive function and simplify a structure of the touch display substrate.

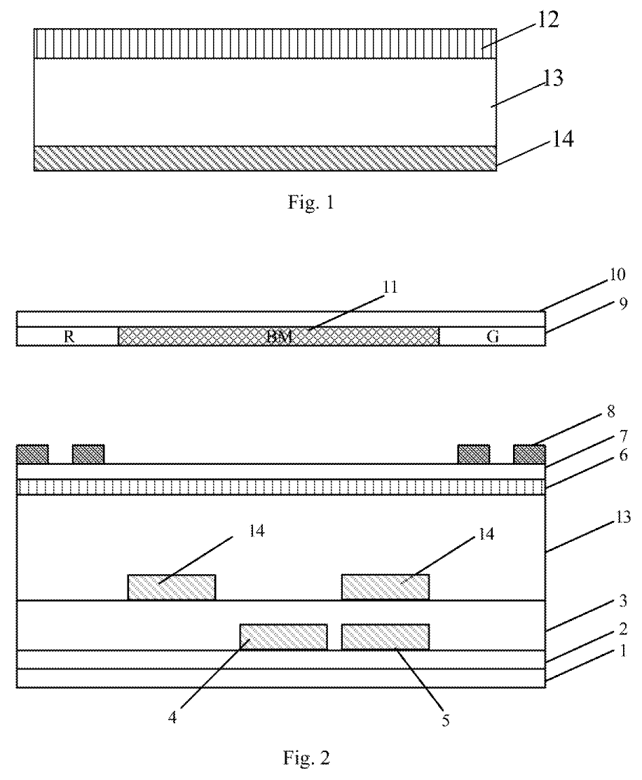

In some embodiments, the present disclosure provides a pressure sensitive unit used in the touch display substrate in the touch display device. The touch display device provided in the present disclosure may be an embedded touch display device or a non-embedded touch display device. FIG. 1 shows a structural schematic diagram of the pressure sensitive unit. The pressure sensitive unit includes a first pressure sensitive electrode 12, a second pressure sensitive electrode 14, and a piezoelectric layer 13 arranged between the first pressure sensitive electrode 12 and the second pressure sensitive electrode 14.

In some embodiments, a material for forming the first pressure sensitive electrode 12 may be different from or same as that for forming the second pressure sensitive electrode 14. The piezoelectric layer 13 may be formed of a transparent piezoelectric material. For example, the piezoelectric layer 13 may be formed of Polyvinylidene fluoride (PVDF). Under a condition that at least one of the first pressure sensitive electrode 12 or the second pressure sensitive electrode 14 is not applied with an electrical signal and thus there is no electric field between the first pressure sensitive electrode 12 and the second pressure sensitive electrode 14, the piezoelectric layer 13 is actually a transparent insulation material layer and does not affect a display effect. Under a condition that both the first pressure sensitive electrode 12 and the second pressure sensitive electrode 14 are applied with electrical signals and thus an electric field is generated between the first pressure sensitive electrode 12 and the second pressure sensitive electrode 14, the PVDF layer exhibits a piezoelectric characteristic. For example, a base voltage such as 0V is applied to the first pressure sensitive electrode 12 and a reference voltage such as 3V is applied to the second pressure sensitive electrode 14. Since a voltage difference exists between the first pressure sensitive electrode 12 and the second pressure sensitive electrode 14, the PVDF layer exhibits the piezoelectric characteristic. Under a condition that a pressure is applied onto the PVDF layer, an electrical potential of at least one of the first pressure sensitive electrode 12 or the second pressure sensitive electrode 14 may be changed. Therefore, through detecting an electrical potential of at least one of the first pressure sensitive electrode 12 or the second pressure sensitive electrode 14, the pressure applied onto the PVDF layer may be detected. The pressure detection circuit may be integrated with the touch display substrate, or may be arranged to be separated with the touch display substrate.

The touch display substrate in some embodiments of the present disclosure includes the above pressure sensitive unit. The touch display device mentioned in the present disclosure may be an in-cell touch display device, such as a touch liquid crystal display device (LCD), a light-emitting diode (LED) touch display device, or an organic light-emitting diode (OLED) touch display device. In the present disclosure, a common electrode in the touch display device is re-used as the first pressure sensitive electrode shown in FIG. 1, and the second pressure sensitive electrode is added, and the piezoelectric layer, such as the PVDF layer, is added between the first pressure sensitive electrode and the second pressure sensitive electrode. In a case that the touch display substrate implements a display function, the second pressure sensitive electrode is not applied with an electrical voltage, and no voltage difference exists between the common electrode and the second pressure sensitive electrode, and in such a case, the piezoelectric layer is equivalent to a transparent insulation layer and does not affect the display function. In a case that the touch display substrate does not display, the second pressure sensitive electrode is applied with the electrical voltage so that a voltage difference exists between the common electrode and the second pressure sensitive electrode, and the piezoelectric layer exhibits the piezoelectric characteristic and thus a magnitude of a pressure may be detected.

In some embodiments of the present disclosure, an in-cell touch display device including the above touch display substrate including the above pressure sensitive unit may include a first pressure sensitive line connected to the first pressure sensitive electrode; and a second pressure sensitive line connected to the second pressure sensitive electrode. Pressure sensitive signals may be transferred to a pressure detection circuit through the first pressure sensitive line and the second pressure sensitive line, so as to implement pressure sensitive and identification functions.

Furthermore, the touch display substrate may include a touch signal line connected to the common electrode, wherein the touch signal line is re-used as the first pressure sensitive line. In this way, no additional line is manufactured as the first pressure sensitive line and thereby a structure of the touch display substrate is simplified. Of course, a first pressure sensitive line different from the touch signal line may be manufactured specifically.

Further, the touch signal line and data lines on the touch display substrate are in a same layer and formed of same materials. In this way, the touch signal line and the data lines may be formed simultaneously in a same patterning process, and a manufacturing process of the touch display substrate may be simplified. Optionally, the touch signal line may also be manufactured by using a separate metal layer.

In some embodiments, the touch display substrate may implement a display function at different time stages. In a time stage during which the touch display substrate implements the display function, a common voltage signal is inputted to the common electrode; and in a time stage during which the touch display substrate implements a touch detection function, a touch signal is inputted to the common electrode; and in a time stage during which the touch display substrate performs a pressure detection function, a base voltage signal is inputted to the common electrode.

In some embodiments, the second pressure sensitive electrode is formed of a metal, has a superior electrical-conductive performance, and in order to avoid the second pressure sensitive electrode from affecting a display function, the second pressure sensitive electrode is located at a non-aperture region of the touch display substrate.

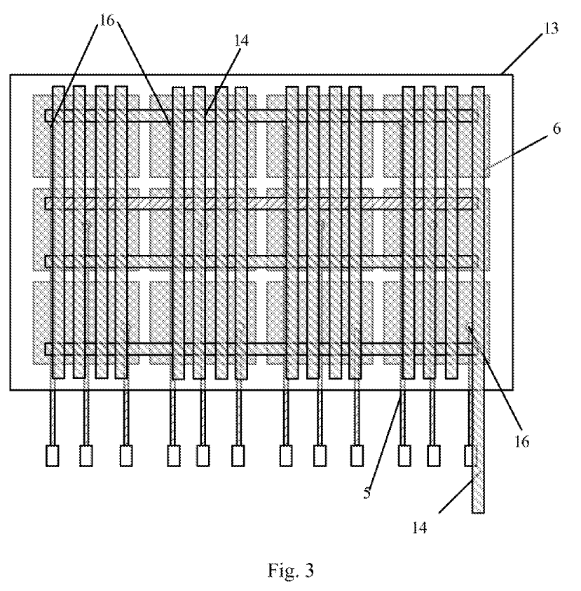

FIG. 2 is a structural schematic diagram of a touch display panel according to some embodiments of the present disclosure; and FIG. 3 is a planar schematic diagram of a touch display panel according to some embodiments of the present disclosure. As shown in FIG. 2 and FIG. 3, the touch display panel shown in FIG. 2 may be the in-cell touch display panel and may include a color filter substrate and an array substrate. The array substrate may implement the touch function and the display function, and accordingly is also called the touch display substrate in the present disclosure. In some embodiments, the color filter substrate includes a black matrix 11 and color light-filtering units 9 on a second base substrate 10. The touch display substrate may include a first base substrate 1, a thin film transistor (TFT) array layer 2 on the first base substrate 1, a data line 4 or data lines 4 on the TFT array layer 2, wherein the data line 4 is connected to (such as directly connected to or electrically connected to) a drain electrode of a thin film transistor, an insulation layer 3 covering the data line 4, second pressure sensitive electrodes 14 on the insulation layer 3, a piezoelectric layer 13 covering the second pressure sensitive electrodes 14, a common electrode 6 on the piezoelectric layer 13, a passivation layer 7 covering the common electrode 6, and pixel electrodes on the passivation layer 7. Thin film transistors included in the TFT array layer 2 may be top-gate-type thin film transistors or bottom-gate-type thin film transistors.

Although the data line 4 in FIG. 2 is displayed to be on the TFT array layer 2, the data line 4 may be below the TFT array layer 2 in some embodiments of the present disclosure, and such a case is also within a protection scope of the present disclosure.

Referring to FIG. 3, the common electrode 6 on the touch display substrate may include a plurality of independent common electrodes 6 arranged in a matrix form. Each of the plurality of independent common electrodes 6 corresponds to one or more pixels. The common electrodes 6 may be re-used as touch electrodes, and may also be re-used as the first pressure sensitive electrodes in the pressure sensitive unit, such as the first pressure sensitive electrode 12 shown in FIG. 1.

The touch display substrate shown in FIG. 2 further includes touch signal lines 5. The touch signal lines 5 and the data lines 4 are in a same layer and formed of a same material. The touch signal lines 5 are connected to (such as directly connected to or electrically connected to) the common electrodes 6 through via-holes 16 penetrating through the insulation layer 3 and the piezoelectric layer 13 so that the common electrodes 6 are connected to a touch circuit and a pressure detection circuit and the touch function, the pressure detection function and the display function are implemented at different time stages. The common electrodes 6 may be re-used as self-capacitance type touch electrodes, and each of the common electrodes 6 is independently applied with a touch signal and receives a feedback signal.

The second pressure sensitive electrode 14 is connected to the pressure detection circuit through the second pressure sensitive line. The pressure detection circuit may be arranged outside the touch display substrate or be integrated inside the touch display substrate.

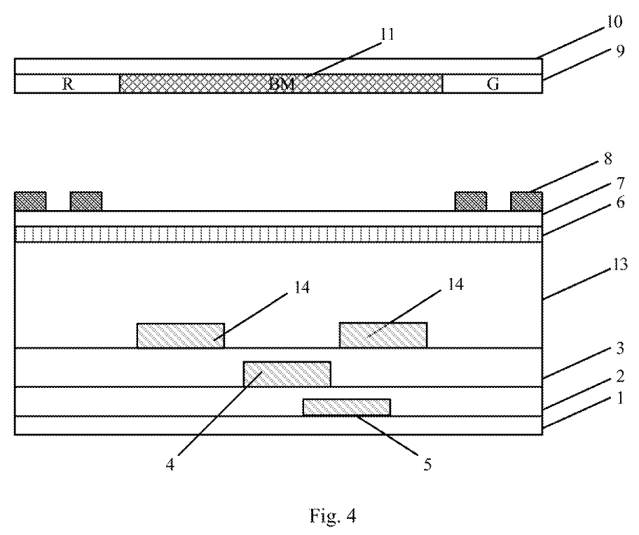

The second pressure sensitive electrode 14 is formed of a metal. In order to avoid the second pressure sensitive electrode 14 from affecting the display function, the second pressure sensitive electrode 14 is arranged at the non-display region of the touch display substrate. As shown in FIG. 4 the second pressure sensitive electrode 14 is arranged to correspond to the black matrix 11 on the color filter substrate. Thus, an orthographic projection of the second pressure sensitive electrode 14 on the color filter substrate falls within in the black matrix 11. In such a way, the second pressure sensitive electrode 14 may not affect an aperture ratio of the touch display device. In the embodiments of the present disclosure, each of the common electrodes corresponds to at least one second pressure sensitive electrode extending in a horizontal direction and at least two second pressure sensitive electrodes extending in a vertical direction. The at least one second pressure sensitive electrode extending in the horizontal direction corresponds to a same row of common electrodes of the plurality of common electrodes arranged in the matrix form, and the at least two second pressure sensitive electrodes extending in the vertical direction correspond to a same column of common electrodes of the plurality of common electrodes arranged in the matrix form. The second pressure sensitive electrode extending in the horizontal direction intersects with the second pressure sensitive electrodes extending in the vertical direction and is electrically connected to the second pressure sensitive electrodes extending in the vertical direction. A position at which each second pressure sensitive electrode extending in the horizontal direction overlaps with each of the second pressure sensitive electrodes extending in the vertical direction is within an area of one of the common electrodes.

When the touch display device operates, a display period of one image frame of the touch display device is divided into three time stages, i.e., the touch time stage, the display time stage and the pressure detection time stage. In the display time stage and the touch time stage, the second pressure sensitive electrodes 14 are not inputted with signals, and no voltage difference exists between the common electrodes 6 and the second pressure sensitive electrodes 14. In such a case, the piezoelectric layer 13 is equivalent to a transparent insulation layer and does not affect the display function. In the pressure detection time stage, electrical signals are inputted to the second pressure sensitive electrodes 14, and a voltage difference exists between the common electrodes 6 and the second pressure sensitive electrodes 14. The piezoelectric layer 13 exhibits the piezoelectric characteristic and thus the magnitude of the pressure may be detected.

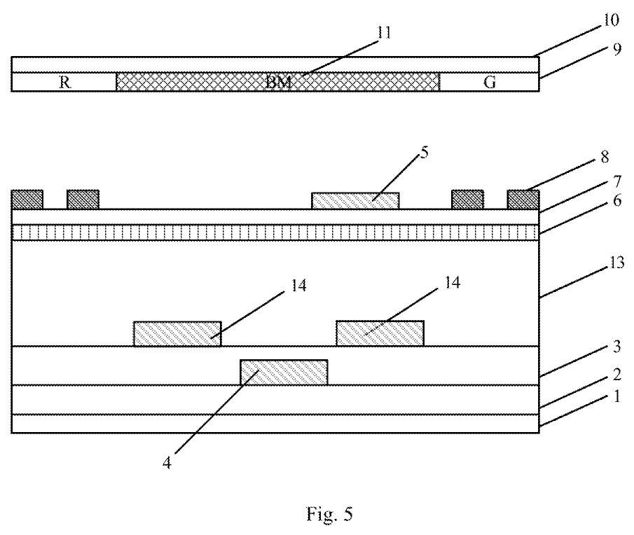

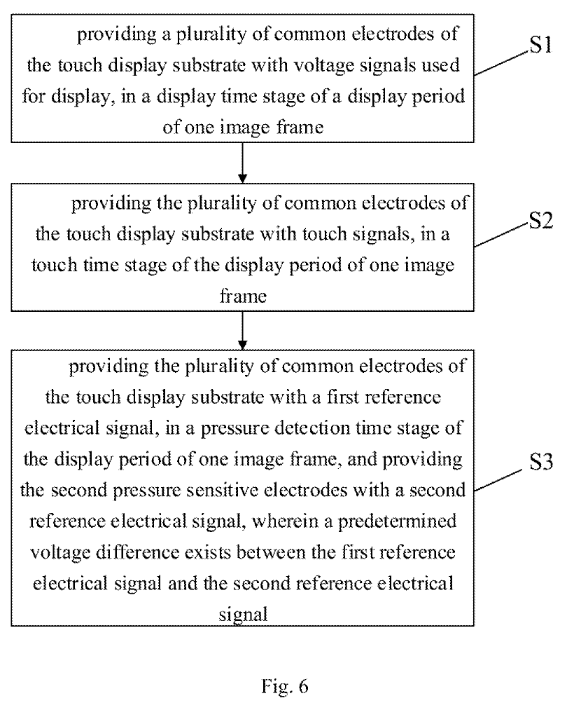

FIG. 4 and FIG. 5 are structural schematic diagrams of a touch display panel including a touch display substrate in some embodiments of the present disclosure. Structures of the touch display panels shown in FIG. 4 and FIG. 5 are basically same as that of the touch display panel shown in FIG. 2. A difference between the structures shown in FIG. 4 and FIG. 5 and the structure shown in FIG. 2 may be that, in FIG. 4, the touch signal line 5 and gate lines of the touch display substrate are in a same layer and formed of a same material; in FIG. 5, the touch signal line 5 and pixel electrodes of the touch display substrate are in a same layer and formed of a same material. In FIG. 4, in a case that thin film transistors (TFTs) included in the thin film transistor (TFT) array layer 2 are bottom-gate type thin film transistors, the touch display substrate includes a gate insulation layer on the gate lines and below the insulation layer 3, and the touch signal line 5 is connected to (such as directly connected or electrically connected to) the common electrode 6 through the via-hole 16 penetrating through the gate insulation layer (no shown), the insulation layer 3 and the piezoelectric layer 13, and connects the common electrode 6 to the touch circuit and the pressure detection circuit. In a case that the thin film transistors included in the TFT array layer 2 are top-gate type TFTs, the touch signal line 5 is connected to (such as directly connected to or electrically connected to) the common electrode 6 through a via-hole 16 penetrating through the insulation layer 3 and the piezoelectric layer 13, and connects the common electrode 6 to the touch circuit and the pressure detection circuit. In FIG. 5, the touch signal line 5 is connected to (such as directly connected to or electrically connected to) the common electrode 6 through a via-hole 16 penetrating through the passivation layer, and connects the common electrode 6 to a touch circuit and a pressure detection circuit.

In the embodiments shown in FIG. 2 to FIG. 5, the touch signal line 5 may be located in the non-display region, and a projection of the touch signal line 5 on the first base substrate 10 is within the black matrix 11.

In some embodiments of the present disclosure, a touch display device is also provided and includes the above touch display substrate. The touch display device may be a liquid crystal television, a liquid crystal display, a digital photo frame, a mobile phone, a tablet, or any product or component capable of displaying, wherein the touch display device may further include a flexible circuit board, a printed circuit board and a backplate.

The touch display substrate in the present disclosure may include the common electrodes on the base substrate, the common electrode is re-used as the touch electrode and may further be re-used as the first pressure sensitive electrode of the pressure sensitive unit. In this way, the pressure sensitive unit may be embedded into the touch display substrate without needing to externally add the pressure sensitive unit to the touch display device, and the touch display substrate may be integrated with a pressure sensitive function, a structure of the touch display substrate may be simplified and the touch display device including the touch display substrate may be thinned.

In some embodiments of the present disclosure, a method for controlling a touch display device is further provided. The touch display device may be the touch display device provided above in the present disclosure, such as the touch display device including the touch display panel shown in FIG. 2. The method includes steps S1-S3 as follow.

S1: providing a plurality of common electrodes of the touch display substrate with voltage signals used for display, in a display time stage of a display period of one image frame.

S2: providing the plurality of common electrodes of the touch display substrate with touch signals, in a touch time stage of the display period of one image frame.

S3: providing the plurality of common electrodes of the touch display substrate with a first reference electrical signal, in a pressure detection time stage of the display period of one image frame, and providing the second pressure sensitive electrodes with a second reference electrical signal, wherein a predetermined voltage difference exists between the first reference electrical signal and the second reference electrical signal.

In some embodiments of the present disclosure, the display period of one image frame displayed by the touch display device is divided into three time stages, i.e., the display time stage, the touch time stage and the pressure detection time stage, and the touch display device is driven at different time stages. In the display time stage and the touch time stage, the second pressure sensitive electrodes are not inputted with a signal, and no voltage difference exists between the first pressure sensitive electrodes and the second pressure sensitive electrodes. In such a case, the piezoelectric layer is equivalent to a transparent insulation layer and does not affect the display function. In the pressure detection time stage, the electrical signal is inputted to the second pressure sensitive electrodes, and a voltage difference exists between the first pressure sensitive electrodes and the second pressure sensitive electrodes. The piezoelectric layer exhibits the piezoelectric characteristic and thus the magnitude of the pressure may be detected.

Further, the method includes at least one of a step S4 or a step S5.

S4: detecting, in the pressure detection time stage of the display period of one image frame, a pressure sensitive signal in the first pressure sensitive line connected to the common electrodes.

S5: detecting a pressure sensitive signal in the second pressure sensitive line connected to the second pressure sensitive electrodes.

A magnitude of the pressure applied to the touch display substrate may be determined by detecting the pressure sensitive signal.

Further, under a condition that the common electrode in the touch display substrate is re-used as the first pressure sensitive electrode, the method specifically includes one of steps S6-S8.

S6: providing the common electrode of the touch display substrate with a common voltage signal, in the display time stage of the display period of one image frame.

S7: providing the common electrode of the touch display substrate with a touch signal, in the touch time stage of the display period of one image frame.

S8: in the pressure detection time stage of the display period of one image frame, at least one of (i) providing the common electrode of the touch display substrate with the first reference electrical signal, or (ii) providing the second pressure sensitive electrodes with the second reference electrical signal.

In some embodiments of the present disclosure, the touch display substrate is driven at different time stages, and thus the pressure sensitive unit may be embedded into the touch display substrate without needing to externally add the pressure sensitive unit to the touch display device, and the touch display substrate may be integrated with a pressure sensitive function, a structure of the touch display substrate may be simplified and the touch display device may be thinned.

Unless defined otherwise, technical terms or scientific terms used herein should have common meanings understood by those of ordinary skilled in the art to which the present disclosure belongs. Words such as “first”, “second” and the like used in the present disclosure do not represent any order, number or importance, but are used to differentiate different components. Words such as “including”, “includes”, “comprising”, “comprises” mean that elements or articles preceding the words incorporate elements or articles behind the words and equivalent elements or articles, but do not exclude other elements or articles. Such words as “connecting”, “connected” or the like are not restricted to physical or mechanical connections, but can include electrical connections, whether they are direct or in-direct. Such words as “upper”, “lower”, “left”, “right” and the like are only used to represent relative positional relations. When an absolute relation of a described object is changed, a relative positional relation of the described object is also changed accordingly.

It may be understood that, when an element such as “film”, “layer”, “region” or “substrate” are described as “below” or “above” another element, the element may be “directly under” or “directly below” the another element, or there may be an intervening element.

The above described embodiments of the present disclosure are optional embodiments. It should be noted that numerous modifications and embellishments may be made by one of ordinary skills in the art without departing from the spirit of the present disclosure, and such modifications and embellishments also fall within the scope of the present disclosure.

1. A touch display substrate, comprising:
a plurality of first electrodes on a base substrate and independent from each other, wherein each of the plurality of first electrodes is configured to be used as an electrode used for display in a display time stage, be used as a touch electrode in a touch time stage and be used as a first pressure sensitive electrode in a pressure detection time stage;
a plurality of second pressure sensitive electrodes corresponding to the plurality of first electrodes on the base substrate; and
a piezoelectric layer between the plurality of first electrodes and the plurality of second pressure sensitive electrodes.

2. The touch display substrate according to claim 1, further comprising:
a plurality of first pressure sensitive lines, wherein each of the first pressure sensitive lines is connected to one of the plurality of first electrodes corresponding to the each of the first pressure sensitive lines; and
a second pressure sensitive line, connected to the plurality of second pressure sensitive electrodes.

3. The touch display substrate according to claim 2, wherein the plurality of first pressure sensitive lines and data lines on the touch display substrate are in a same layer and are formed of a same material, or
the plurality of first pressure sensitive lines and gate lines on the touch display substrate are in a same layer and are formed of a same material, or
the plurality of first pressure sensitive lines and pixel electrodes on the touch display substrate are in a same layer and are formed of a same material.

4. The touch display substrate according to claim 2, wherein the plurality of second pressure sensitive electrodes is formed of a metal, and each of the plurality of second pressure sensitive electrodes is in a non-aperture region of the touch display substrate.

5. The touch display substrate according to claim 3, further comprising:
a thin film transistor (TFT) array layer on the base substrate;
the data lines on the TFT array layer; and
an insulation layer on the TFT array layer and covering the data lines;
wherein the plurality of second pressure sensitive electrodes is on the insulation layer, the piezoelectric layer is on the plurality of second pressure sensitive electrodes and covers the insulation layer, and the plurality of first electrodes is on the piezoelectric layer.

6. The touch display substrate according to claim 1, wherein the piezoelectric layer is formed of Polyvinylidene fluoride.

7. The touch display substrate according to claim 5, wherein under a condition that the plurality of first pressure sensitive lines and data lines on the touch display substrate are in a same layer and are formed of a same material, each of the plurality of first pressure sensitive lines is connected to one of the first electrodes through a corresponding via-hole penetrating through the insulation layer and the piezoelectric layer;
under a condition that the plurality of first pressure sensitive lines and gate lines on the touch display substrate are in a same layer and are formed of the same material, if thin film transistors (TFTs) comprised in the TFT array layer are bottom-gate type TFTs, the each of the plurality of first pressure sensitive lines is connected to one of the first electrodes through a corresponding via-hole, wherein the corresponding via-hole penetrates through a gate-insulation layer above the gate lines and below the insulation layer, through the insulation layer and through the piezoelectric layer; if the TFTs comprised in the TFT array layer are top-gate type TFTs, then each of the plurality of first pressure sensitive lines is connected to one of the first electrodes through a corresponding via-hole penetrating through the insulation layer and the piezoelectric layer; or
under a condition that the plurality of first pressure sensitive lines and pixel electrodes on the touch display substrate are in a same layer and are formed of a same material, each of the plurality of first pressure sensitive lines is connected to one of the first electrodes through a corresponding via-hole penetrating through a passivation layer on the first electrodes.

8. The touch display substrate according to claim 2, wherein the piezoelectric layer directly contacts with both the plurality of first electrodes and the plurality of second piezoelectric sensitive electrodes.

9. The touch display substrate according to claim 1, wherein the plurality of first pressure sensitive lines is used as the touch signal lines in the touch time stage.

10. The touch display substrate according to claim 1, wherein the plurality of first electrodes is a plurality of common electrodes arranged in a matrix form, each of the plurality of common electrodes corresponds to at least one second pressure sensitive electrode extending in a horizontal direction and at least two second pressure sensitive electrodes extending in a vertical direction; the at least one second pressure sensitive electrode extending in a horizontal direction corresponds to a same row of common electrodes of the plurality of common electrodes arranged in the matrix form, and the at least two second pressure sensitive electrodes extending in the vertical direction correspond to a same column of common electrodes of the plurality of common electrodes arranged in the matrix form.

11. The touch display substrate according to claim 10, wherein the at least one second pressure sensitive electrode extending in the horizontal direction intersects with, overlaps with, and is electrically connected with the at least two second pressure sensitive electrodes extending in the vertical direction, and
a position at which each second pressure sensitive electrode extending in the horizontal direction overlaps with each second pressure sensitive electrode extending in the vertical direction is within a region of one of the common electrodes.

12. A touch display device, comprising:
a touch display substrate according to claim 1.

13. A method for controlling a touch display device, the touch display device being the touch display device according to claim 12, the method comprising:
providing the plurality of first electrodes of the touch display substrate with common voltage signals, in the display time stage of the display period of one image frame;
providing the plurality of first electrodes of the touch display substrate with a touch signal, in the touch time stage of the display period of the one image frame; and
providing the plurality of first electrodes of the touch display substrate with a first reference electrical signal, in the pressure detection time stage of the display period of the one image frame, and providing the plurality of second pressure sensitive electrodes with a second reference electrical signal, wherein a predetermined voltage difference exists between the first reference electrical signal and the second reference electrical signal.

14. The method according to claim 13, further comprising: at least one of following (i) or (ii):
(i) detecting, in the pressure detection time stage of the display period of the one image frame, a pressure sensitive signal in a corresponding first line connected to the each of the plurality of first electrodes;
(ii) detecting, in the pressure detection time stage of the display period of the one image frame, a pressure sensitive signal in the second pressure sensitive line connected to the plurality of pressure sensitive electrodes.

15. The method according to claim 13, wherein, the plurality of first electrodes is a plurality of common electrodes, and the method further comprises:
providing the plurality of common electrodes of the touch display substrate with common voltage signals, in the display time stage of the display period of one image frame;
providing the plurality of common electrodes of the touch display substrate with touch signals, in the touch time stage of the display period of the one image frame; and
in the pressure detection time stage of the display period of the one image frame, at least one of (i) providing the plurality of common electrodes of the touch display substrate with the first reference electrical signal, or (ii) providing the plurality of second pressure sensitive electrodes with the second reference electrical signal.

16. The touch display substrate according to claim 3, wherein the plurality of second pressure sensitive electrodes is formed of a metal, and each of the plurality of second pressure sensitive electrodes is in a non-aperture region of the touch display substrate.

17. The touch display substrate according to claim 2, wherein the plurality of first electrodes is a plurality of common electrodes arranged in a matrix form, each of the plurality of common electrodes corresponds to at least one second pressure sensitive electrode extending in a horizontal direction and at least two second pressure sensitive electrodes extending in a vertical direction; the at least one second pressure sensitive electrode extending in a horizontal direction corresponds to a same row of common electrodes of the plurality of common electrodes arranged in the matrix form, and the at least two second pressure sensitive electrodes extending in the vertical direction correspond to a same column of common electrodes of the plurality of common electrodes arranged in the matrix form.
